(19) United States
(12) Patent Application Publication
(10) Pub. No.: US 2010/0110817 A1
(43) Pub. Date: May 6, 2010

(54) Semiconductor device and refreshing method

(75) Inventors: Hiromasa Noda, Tokyo (JP); Atsushi Fujikawa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/588,452

(22) Filed: Oct. 15, 2009

(30) Foreign Application Priority Data
Oct. 31, 2008 (JP) 2008-280809

(51) Int. Cl. G11C 7/00; G11C 8/00

(52) U.S. Cl. 365/222; 365/236

(57) ABSTRACT

A semiconductor device comprising a word line wired on a memory bank, a memory cell storing data provided in correspondence with the word line and a sense amplifier provided in correspondence with the word line, refreshing the memory cell corresponding to the word line selected by a row address that has been generated, including refresh counter 2 that generates a counter address corresponding to the row address and sequentially counts up the counter address, controller 1 that determines and outputs, upon receiving a refresh command instructing that a refresh operation be performed, first line number information and second line number information determining a number of word lines to be started based on the counter address and word line selector 3 that determines the row address according to the first line number information and the second line number information, and the counter address.

This application is based upon and claims the benefit of priority from Japanese patent application No. 2008-280809, filed on Oct. 31, 2008, the disclosure of which is incorporated herein in its entirety by reference.

### BACKGROUND OF THE INVENTION

1. Field of the Invention

The present invention relates to a semiconductor device requiring a refresh to hold stored data and a refreshing method.

2. Description of the Related Art

A DRAM (Dynamic Random Access Memory), which is a volatile memory, stores data by accumulating a charge in a capacitor of a memory cell. The charge accumulated in this capacitor decreases with time, and therefore data is lost if the charge is not refreshed. Therefore, a refresh operation in which a charge is supplied to the capacitor of the memory cell is indispensable for the DRAM to prevent data from being lost.

During a refresh operation, refresh commands are inputted to a DRAM a specified number of times for a certain period and access is made to all memory cells to perform a data reading operation of reading charge stored in a capacitor of each memory cell and a data rewriting operation of supplying a charge corresponding to the data read to the capacitor of each memory cell.

For example, the standard of a 1 G (Giga)-bit DDR2-SDRAM (Double Data Rate2 Synchronous Dynamic Random Access Memory) defines that refresh commands are inputted 8 K times for a period of 64 ms. To be more specific, the standard defines that an average of an interval at which refresh commands are inputted is 7.8 μs as a tREFI (Required Average Periodic Refresh Interval).

Accessing all memory cells 8 K times with a 1 G-bit DRAM requires a 128 K-bit memory cell to be selected with one refresh command, and 8 banks of 16 K memory cells per bank of a memory array are normally selected simultaneously.

In the case of a word configuration ×8, for which there is high demand, in a server or personal computer, since a page size (number of memory cells simultaneously selected with one word line) is defined to be 8 K, two word lines per bank are simultaneously selected with one refresh command.

On the other hand, although charge is supplied to the capacitor of the memory cell from which data is read even in a normal data reading operation from the memory cell, only one bank is simultaneously selected and only one word line is selected during a data reading operation.

That is, during a refresh operation, charge is supplied simultaneously to capacitors of many memory cells, and therefore a great burden is placed on a power supply system of the memory array compared to a normal data reading operation from the memory cell.

Especially when an over-drive scheme using compensation capacitance to supply a charge is applied during a refresh, a charge needs to be supplied to memory cells corresponding to two word lines, and therefore compensation capacitance twice the amount necessary for a normal data reading operation from the memory cells is necessary. The “over-drive scheme” is one of the sense amplifier operation schemes effective in securing a data reading operation margin of memory cells.

Here, a technique for reducing the magnitude of peak current in a refresh operation is disclosed, for example, in Japanese Patent Laid-Open No. 10-188562.

The technique disclosed in Japanese Patent Laid-Open No. 10-188562 divides a plurality of sense amplifiers corresponding to a plurality of selected word lines into two or more groups in a refresh operation based on the sense amplifier operation scheme and distributes timings at which the divided sense amplifiers are started. This allows a burden on a power supply system of the memory array to be evenly distributed.

Using the technique disclosed in Japanese Patent Laid-Open No. 10-188562 allows a peak-time burden on the power supply system of the memory array to be reduced during a refresh operation.

However, when the starting operation timings of the sense amplifiers are distributed as in the case of the technique disclosed in Japanese Patent Laid-Open No. 10-188562, there is a problem in which the number of memory cells that can be refreshed by one refresh command is reduced.

### SUMMARY

A semiconductor device including a word line wired on a memory bank, a memory cell that stores data provided in correspondence with the word line and a sense amplifier provided in correspondence with the word line, for refreshing the memory cell corresponding to the word line selected by a row address generated, including: a refresh counter that generates a counter address corresponding to the row address and sequentially counts up the counter address; a controller that determines and outputs, upon receiving a refresh command instructing that a refresh operation be performed, first line number information and second line number information that determine the number of word lines to be started based on the counter address; and a word line selector that determines and outputs the row address according to the first line number information and the second line number information and the counter address.

Furthermore, a semiconductor device including: a memory bank divided into a first region and a second region; a first word line provided in correspondence with the first region; a second word line provided in correspondence with the second region; a first memory cell provided in correspondence with the first word line for storing data; a second memory cell provided in correspondence with the second word line for storing data; a first sense amplifier provided in correspondence with the first word line; a second sense amplifier provided in correspondence with the second word line; a refresh counter that generates a counter address corresponding to a row address that selects the first word line and the second word line and sequentially counts up the counter address; and a controller that performs control, upon receiving a refresh command for instructing that a refresh operation be performed, so as to perform refreshing a plurality of times within a refresh period.

Furthermore, a refreshing method in a semiconductor device including a word line wired on a memory bank, a memory cell that stores data provided in correspondence with the word line and a sense amplifier provided in correspondence with the word line, for refreshing the memory cell corresponding to the word line selected by a row address generated, including: a process of selecting, upon receiving a refresh command for instructing that a refresh operation be performed, first line number information and second line number information that determines the number of word lines to be started based on a counter address indicated by a refresh counter; and a process of determining the row address according to the first line number information and second line number information, and the counter address.

Thus, the semiconductor device of the present invention selects a word line twice upon receiving one refresh command, and can thereby increase the number of memory cells that can be refreshed by receiving one refresh command. Furthermore, when a plurality of word lines are selected, sense amplifiers corresponding to the plurality of word lines are not simultaneously started, and it is therefore possible to reduce the burden on a power supply system of a memory array.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configuration of an embodiment of a semiconductor device according to the present invention;

FIG. 2 is a block diagram showing an example of the configuration of the controller shown in FIG. 1;

FIG. 3 is a timing chart of signals during a refresh operation in the controller shown in FIG. 1 and FIG. 2;

FIG. 4 shows an example of assignment of row addresses in a memory bank of the memory array of the semiconductor device shown in FIG. 1;

FIG. 5 shows a configuration example of part of the memory bank shown in FIG. 4;

FIG. 6 is a flowchart illustrating the refresh operation in the semiconductor device shown in FIG. 1 to FIG. 5; and

FIG. 7 is an operation waveform diagram showing voltage variations of the word lines and bit lines shown in FIG. 5.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

Preferred embodiments of the present invention will now be described with reference to the drawings.

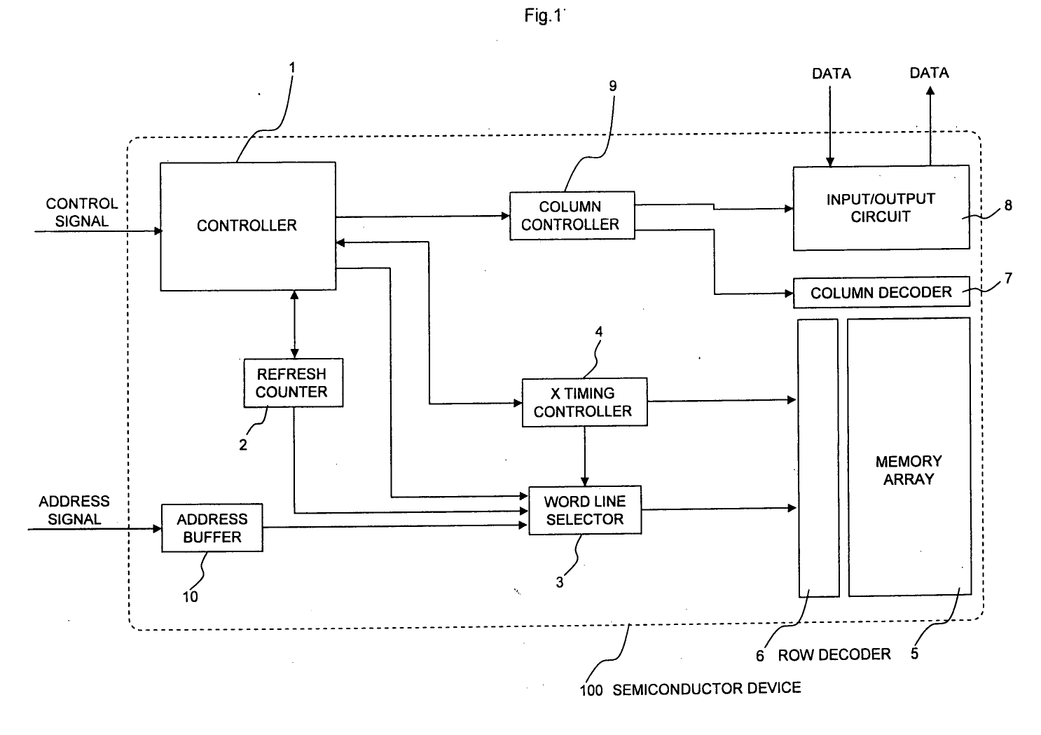

FIG. 1 is a block diagram showing a configuration of an embodiment of a semiconductor device according to the present invention.

As shown in FIG. 1, semiconductor device 100 of the present embodiment is provided with controller 1, refresh counter 2, word line selector 3, X timing controller 4, memory array 5, row decoder 6, column decoder 7, input/output circuit 8, column controller 9 and address buffer 10.

Memory array 5 is constructed of a plurality of memory banks (not shown) having many memory cells (not shown) that store data. The memory bank is constructed of a plurality of word lines, a plurality of bit lines that cross the word lines and a plurality of memory cells disposed at points of intersection of the word lines and the bit lines. Details of the configuration of the memory bank will be described later.

Controller 1 is intended to control operations of semiconductor device 100, receives a control signal inputted from the outside of semiconductor device 100 and controls operations of the respective sections of semiconductor device 100. Examples of control signals inputted from the outside of semiconductor device 100 to controller 1 include a row address strobe signal (RAS), column address strobe signal (CAS) and write enable signal (WE). Furthermore, the “outside of semiconductor device 100” is, for example, a DRAM controller (not shown). Furthermore, upon receiving a refresh command inputted from the outside of semiconductor device 100, controller 1 generates a counter address to specify a row address of a word line in refresh counter 2. Furthermore, controller 1 instructs X timing controller 4 to generate the timing of starting a sense amplifier (not shown) and a word line, and instructs word line selector 3 about the number of word lines to be started simultaneously. Details of operations of controller 1 during a refresh operation will be described later using an operation flow.

Word line selector 3 determines the number of word lines to be selected and addresses thereof to perform a refresh operation according to the value of the counter address generated by refresh counter 2 and the instruction from controller 1 and outputs information indicating the determined number of word lines and addresses as first line number information or second line number information to row decoder 6. Word line selector 3 outputs the counter address outputted from refresh counter 2 as a row address to row decoder 6 during a refresh operation as described above, whereas during a normal operation, word line selector 3 outputs the address outputted from address buffer 10 as a row address to row decoder 6. Furthermore, word line selector 3 makes a redundancy judgment to judge whether or not a word line corresponding to the address outputted from refresh counter 2 or address buffer 10 has been relieved. If the word line has been relieved, word line selector 3 outputs the relieved redundant address as the row address to row decoder 6, whereas when the word line has not been relieved, word line selector 3 outputs the address outputted from refresh counter 2 or address buffer 10 as the row address to row decoder 6.

Refresh counter 2 generates a counter address to specify the word line during a refresh operation based on the instruction of controller 1 and counts a counter address value. The address of the present embodiment is made up of 14 bits from X0 to X13, and X13 is the highest address, whereas X13 is the lowest address in refresh counter 2, and addresses are arranged as X13, X0 to X12 in ascending order. Furthermore, the addresses of X0 to X13 are outputted from refresh counter 2 to word line selector 3, whereas only the address of X13 is outputted from refresh counter 2 to controller 1.

X timing controller 4 outputs an activation signal for controlling timing to start a word line or a sense amplifier, timing for word line selector 3 to output the row address to row decoder 6 according to the instruction from controller 1. When starting sense amplifiers corresponding to a plurality of word lines, X timing controller 4 outputs an activation signal with the start timing shifted for each word line. Details of this operation will be described later in an operation flow.

Row decoder 6 selects a word line of memory array 5 according to the row address for receiving the output from word line selector 3.

Column decoder 7 selects a bit line of memory array 5 according to the column address for receiving the output from column controller 9.

Input/output circuit 8 performs input/output control over data written from the outside of semiconductor device 100 to the memory cell of memory array 5 and data read from the memory cell of memory array 5 to the outside of semiconductor device 100.

Column controller 9 starts a Y switch (not shown) according to an instruction from controller 1 and a column address inputted from address buffer 10 and connects the bit line corresponding to the column address and input/output circuit 8. In FIG. 1, the description of the wiring between address buffer 10 and column controller 9 is omitted.

Address buffer 10 temporarily stores an address signal inputted from the outside of semiconductor device 100.

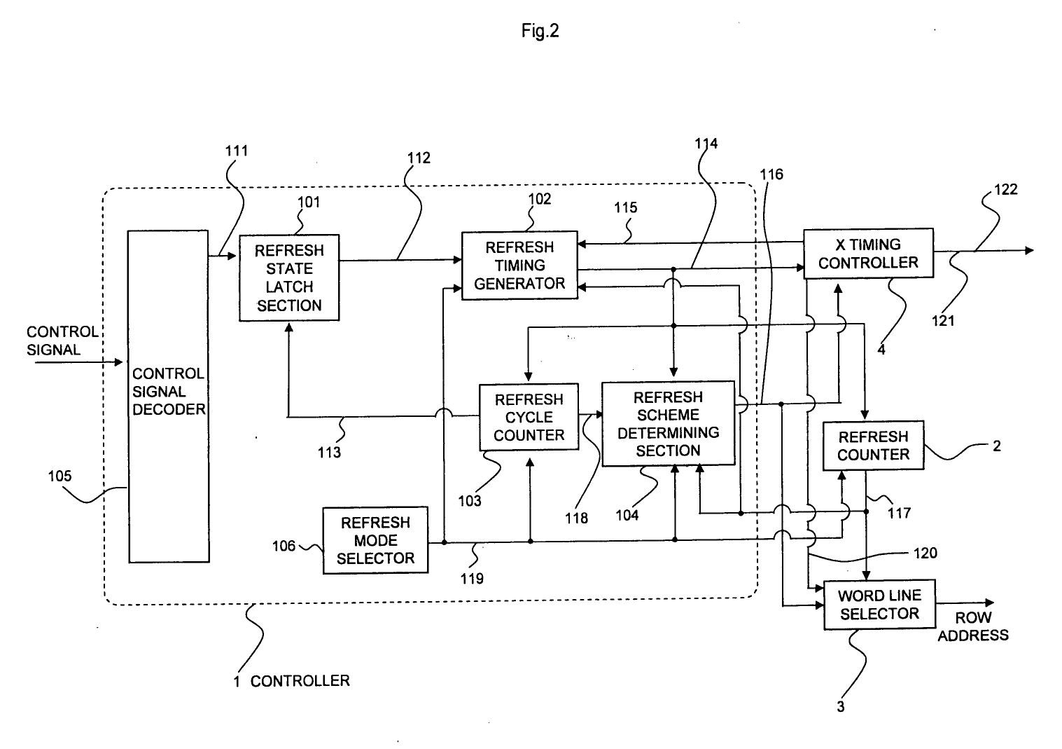

FIG. 2 is a block diagram showing an example of the configuration of controller 1 shown in FIG. 1.

Controller 1 shown in FIG. 1 is provided with refresh state latch section 101, refresh timing generator 102, refresh cycle counter 103, refresh scheme determining section 104, control signal decoder 105 and refresh mode selector 106 as shown in FIG. 2.

Control signal decoder 105 receives a refresh command which is one of the control signals from the outside of semiconductor device 100 shown in FIG. 1 and generates internal refresh signal 111.

Upon detecting internal refresh signal 111 that was generated, refresh state latch section 101 sets internal refresh state signal 112 indicating a refresh operation state to high level. Internal refresh signal 111 is a one-shot pulse signal. Furthermore, upon detecting reset signal 113 to end a refresh operation, refresh state latch section 101 resets internal refresh state signal 112 which has been set to the high level to low level.

While internal refresh state signal 112 is set to the high level, refresh timing generator 102 generates refresh clock signal 114 that is used to control the refresh operation once or twice consecutively. First, when internal refresh state signal 112 is driven high, refresh timing generator 102 generates refresh clock signal 114. Upon receiving end signal 115 from X timing controller 4, if the internal refresh state signal is in a high level state, refresh timing generator 102 generates refresh clock signal 114 again. On the other hand, upon receiving end signal 115 from X timing controller 4, if the internal refresh state signal is in a low level state, refresh timing generator 102 does not generate refresh clock signal 114 again. The number of times refresh clock signal 114 is generated consecutively is determined by counter address 117 that is received from refresh counter 2 when internal refresh state signal 112 is driven high, but details will be described later.

Refresh cycle counter 103 generates reset signal 113 according to the count of refresh clock signal 114 received from refresh timing generator 102. Refresh scheme determining section 104 determines refresh scheme determining signal 116 from counter address 117 outputted from refresh counter 2 and cycle address 118 outputted from refresh cycle counter 103 based on the timing of refresh clock signal 114 and outputs refresh scheme determining signal 116 to X timing controller 4 and word line selector 3.

Refresh mode selector 106 outputs refresh mode report signal 119 indicating the selected refresh operation scheme into controller 1. The refresh operation scheme is set through a mode register setting, fuse or the like. Either the refresh operation scheme of the present invention or a general refresh operation scheme is selected in this way.

Here, timings of signals generated during a refresh operation in controller 1 shown in FIG. 1 and FIG. 2 will be explained.

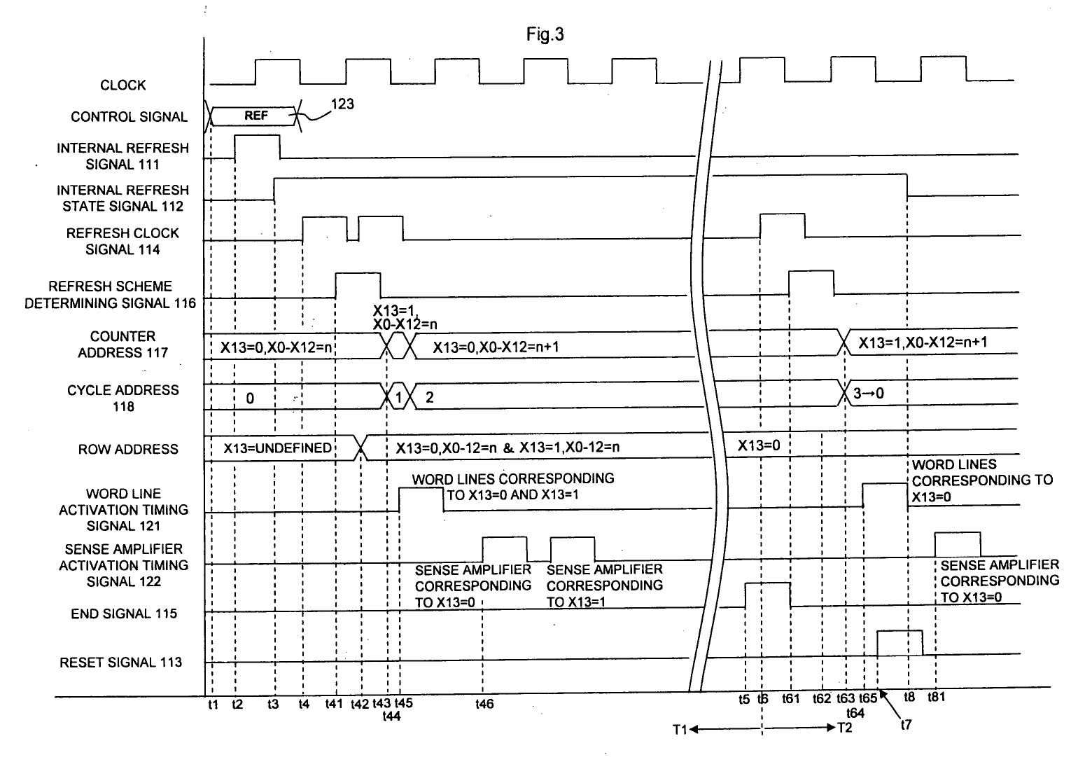

FIG. 3 is a timing chart of signals during a refresh operation in controller 1 shown in FIG. 1 and FIG. 2. This timing chart shows an example where counter address 117 is X13=0, X0 to 12=n at the start of a refresh operation and two refresh operations are performed by one refresh command 123. At the first refresh operation, the word lines corresponding to X13=0, X0 to 12=n and X13=1, X0 to 12=n are started simultaneously. The sense amplifiers corresponding to X13=0, X0 to 12=n are then started and the sense amplifiers corresponding to X13=1, X0 to 12=n are then started (first line number information). At the second refresh operation, the word lines corresponding to X13=0, X0 to 12=n+1 are started and the sense amplifiers corresponding to X13=0, X0 to 12=n+1 are started (second line number information).

First, refresh command 123, which is a control signal, is inputted from the outside of semiconductor device 100 at time t1 and internal refresh signal 111 is thereby generated at time t2.

Refresh state latch section 101 that has detected internal refresh signal 111 sets internal refresh state signal 112 to a high level state at time t3.

Upon detecting that internal refresh state signal 112 is driven high, refresh timing generator 102 generates first refresh clock signal 114 at time t4. Here, since counter address 117 is X13=0 at the start of a refresh operation, refresh timing generator 102 generates refresh clock signal 114 twice consecutively.

Upon detecting that first refresh clock signal 114 has been inputted from refresh timing generator 102, refresh scheme determining section 104 determines a refresh scheme at time t41 from X13 of counter address 117 outputted from refresh counter 2 and cycle address 118 outputted from refresh cycle counter 103. Refresh scheme determining section 104 then outputs a refresh scheme determining signal 116 to word line selector 3 and X timing controller 4.

Here, since counter address 117 is X13=0 and cycle address 118 is 0, refresh scheme determining signal 116 outputted from refresh scheme determining section 104 is the first line number information. Refresh scheme determining section 104 receives refresh clock signal 114 from refresh timing generator 102 twice consecutively, but since refresh scheme determining section 104 has started an operation through first refresh clock signal 114, the operation is never affected by second refresh clock signal 114.

Upon detecting that refresh scheme determining signal 116 has been inputted from refresh scheme determining section 104, word line selector 3 determines a row address to be outputted to row decoder 6 from the information of refresh scheme determining signal 116 and counter address 117.

Upon detecting row address timing signal 120 outputted from X timing controller 4, word line selector 3 outputs the determined row address to row decoder 6 at time t42. Here, since refresh scheme determining signal 116 indicates the first line number information, word line selector 3 outputs the row addresses of X13=0, X0 to 12=n and X13=1, X0 to 12=n to row decoder 6.

Upon detecting refresh clock signal 114 outputted from refresh timing generator 102, refresh counter 2 counts counter address 117 at time t43. Since refresh counter 2 detects refresh clock signal 114 twice consecutively, counter address 117 is sequentially counted from X13=0, X0 to 12=n to X13=1, X0 to 12=n and further to X13=0, X0 to 12=11+1.

Upon detecting refresh clock signal 114 outputted from refresh timing generator 102, refresh cycle counter 103 counts cycle address 118 at time t44. Since refresh cycle counter 103 detects refresh clock signal 114 twice consecutively, cycle address 118 is sequentially counted from 0 to 1 and 2.

Here, the timing at which word line selector 3 detects refresh scheme determining signal 116 outputted from refresh scheme determining section 104 and determines the row address is set so as to be earlier than the timing at which refresh counter 2 and refresh cycle counter 103 detect and count refresh clock signal 114 outputted from refresh timing generator 102.

Upon detecting refresh clock signal 114 outputted from refresh timing generator 102 and refresh scheme determining signal 116 outputted from refresh scheme determining section 104, X timing controller 4 outputs row address timing signal 120 (see FIG. 2) to word line selector 3 within a predetermined time.

X timing controller 4 then outputs word line activation timing signal 121 at time t45 and outputs sense amplifier activation timing signal 122 at time t46. Here, since refresh scheme determining signal 116 indicates the first line number information, X timing controller 4 outputs sense amplifier activation timing signal 122 twice. X timing controller 4 receives refresh clock signal 114 from refresh timing generator 102 twice consecutively, but since X timing controller 4 has started operation by first refresh clock signal 114, the operation is never affected by second refresh clock signal 114.

When the refresh of the memory cell corresponding to the first selected word line is completed, refresh timing generator 102 receives the output of end signal 115 from X timing controller 4 at time t5.

Refresh timing generator 102 then generates second refresh clock signal 114 at time t6. Since this is the second refresh, refresh timing generator 102 generates refresh clock signal 114 once.

Upon detecting that refresh clock signal 114 has been inputted from refresh timing generator 102, refresh scheme determining section 104 determines a refresh scheme from X13 of counter address 117 outputted from refresh counter 2 at time t61 and cycle address 118 outputted from refresh cycle counter 103 and outputs refresh scheme determining signal 116 to word line selector 3 and X timing controller 4. Here, since counter address 117 is X13=0 and cycle address 118 is 2, refresh scheme determining signal 116 outputted from refresh scheme determining section 104 is the second line number information.

Upon detecting that refresh scheme determining signal 116 has been inputted from refresh scheme determining section 104, word line selector 3 determines a row address to be outputted to row decoder 6 from the information of refresh scheme determining signal 116 and counter address 117.

Upon detecting row address timing signal 120 outputted from X timing controller 4, word line selector 3 outputs the determined row address to row decoder 6 at time t62. Here, since refresh scheme determining signal 116 indicates the second line number information, word line selector 3 outputs the row addresses of X13=0, X0 to 12=n+1 to row decoder 6.

Upon detecting refresh clock signal 114 outputted from refresh timing generator 102, refresh counter 2 counts counter address 117 at time t63. Counter address 117 is counted from X13=0, X0 to 12=n+1 to X13=1, X0 to 12=n+1.

Upon detecting refresh clock signal 114 outputted from refresh timing generator 102, refresh cycle counter 103 counts cycle address 118 at time t64. Here, cycle address 118 is counted from 2 to 3. When cycle address 118 becomes 3, refresh cycle counter 103 outputs reset signal 113 to refresh state latch section 101 at time t7. Cycle address 118 is then reset to 0.

Upon detecting refresh clock signal 114 outputted from refresh timing generator 102 and refresh scheme determining signal 116 outputted from refresh scheme determining section 104, X timing controller 4 outputs row address timing signal 120 to word line selector 3 within a predetermined time. X timing controller 4 then outputs word line activation timing signal 121 at time t65 and outputs sense amplifier activation timing signal 122 at time t81. Here, since refresh scheme determining signal 116 indicates the second line number information, X timing controller 4 outputs sense amplifier activation timing signal 122 only once. Upon detecting reset signal 113, refresh state latch section 101 resets internal refresh state signal 112 set to a high level state at time t8 to low level.

As explained above, row addresses are generated twice at refresh counter 2 by one refresh command inputted from the outside of semiconductor device 100, and a word line selection is performed twice. Next, even if refresh timing generator 102 receives end signal 115 from X timing controller 4, internal refresh state signal 112 is not set to a high level state, and therefore refresh timing generator 102 does not output refresh clock signal 114. Therefore, no word line selection is performed.

Here, a case where X13=0 at the start of a refresh operation has been explained, but a case where X13=1 at the start of a refresh operation will be explained below.

When X13=1 at the start of a refresh operation, word lines corresponding to X13=1, X0 to 12=n are started at a first refresh operation and sense amplifiers corresponding to X13=1, X0 to 12=n are started (second line number information). At a second refresh operation, word lines corresponding to X13=0, X0 to 12=n+1 and X13=1, X0 to 12=n+1 are started simultaneously. Sense amplifiers corresponding to X13=0, X0 to 12=n+1 are then started and sense amplifiers corresponding to X13=1, X0 to 12=n+1 are then started (first line number information).

That is, the operation of T1 which is the operation from the refresh start to t6 and the operation of T2 from t6 to the end of the refresh period in FIG. 3 are reversed when X13=0 and when X13=1 at the start of a refresh operation.

Furthermore, refresh scheme determining section 104 determines the first line number information and second line number information from cycle address 118 and X13 of counter address 117, and combinations of the determinations are as follows.

First line number information (X13, cycle address)=(0, 0), (0, 1)

Second line number information (X13, cycle address)=(0, 2), (1, 0)

According to the present embodiment, a word line selection is performed twice by receiving one refresh command and a refresh operation is performed based on the first line number information and the second line number information, but the present embodiment can be changed based on the refresh period and time necessary for the refresh.

For example, a word line selection is performed three times by receiving one refresh command and a refresh operation can be performed in order of the first line number information, first line number information and second line number information. In the present embodiment, operation of refresh timing generator 102, the number of addresses of cycle address 118 of refresh cycle counter 103 and the determining scheme of refresh scheme determining section 104 may be changed.

A case where a word line selection is performed three times by receiving one refresh command will be explained below.

If X13=0 upon detecting the internal refresh state signal 112 is driven high, refresh timing generator 102 generates refresh clock signal 114 twice.

Upon detecting end signal 115, refresh timing generator 102 generates refresh clock signal 114 twice, and then upon detecting end signal 115, refresh timing generator 102 generates refresh clock signal 114 twice.

Furthermore, if X13=0 upon detecting that internal refresh state signal 112 is driven high, refresh timing generator 102 generates refresh clock signal 114 once, twice and twice in that order respectively. In this case, when refresh cycle counter 103 counts cycle address 118 up to 5, and counts 5, refresh cycle counter 103 generates reset signal 113 and resets 5 to 0.

Refresh scheme determining section 104 determines first line number information an second line number information from cycle address 118 and X13 of counter address 117, and combinations of the determinations are as follows.

First line number information (X13, cycle address)=(0, 0), (0, 2), (0, 1), (0, 3)

Second line number information (X13, cycle address)=(0, 4), (1, 0)

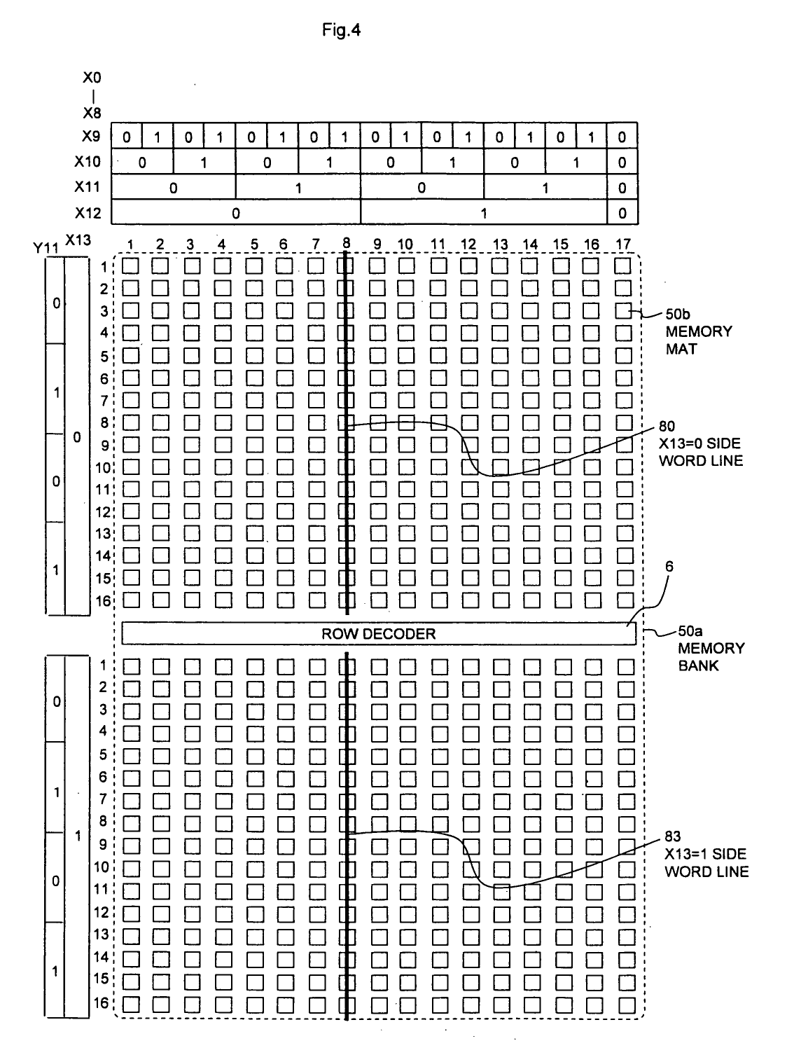

FIG. 4 illustrates an example of assignment of row addresses in the memory bank of memory array 5 of semiconductor device 100 shown in FIG. 1. Here, suppose semiconductor device 100 has a 1 G-bit DRAM/8 banks/word configuration x8.

Memory bank 50a of memory array 5 of semiconductor device 100 shown in FIG. 1 includes a total of 544 memory mats 50b, with 272 memory mats in the upper and lower parts of the figure respectively as shown in FIG. 4.

Each memory mat 50b shown in FIG. 4 includes 512 bit lines, 512 word lines and 256 memory cells.

A word line included in memory mat 50b shown in FIG. 4 is specified using a row address of a total of 14 bits of X0 to X13. In this case, memory mat 50b is specified using a total of 5 bits of X9 to X13. For example, bits X9 to X13 that specify memory mat 50b at the top left of the figure are “00000.” 512 word lines included in memory mat 50b are specified using a total of 9 bits of X0 to X8. That is, the row address of a word line included in memory mat 50b at the top left of the figure is, for example, “0000011100101” and “00000101011111” in which “00000” are common from bits X9 to X13, and bits X0 to X8 are arbitrary bits.

Thus, the present embodiment assumes a case where a higher address is used to select a greater region. For example, bit X13 of “0” indicates the upper part, which is the first region of memory bank 50a in the figure and bit X13 of “1” indicates the lower part, which is the second region of memory bank 50a.

Hereinafter, the first word line where bit X13 in the first region at the top of the figure corresponds to 0 is referred to as a “X13=0 side word line” and the second word line where bit X13 in the second region at the lower part of the figure corresponds to 1 is referred to as a “X13=1 side word line.”

According to the present embodiment, during a refresh operation, one X13=0 side word line 80 where bits X0 to X12 are common in the same memory bank and only bit X13 is different and one X13=1 side word line 83 are selected simultaneously or one by one and a refresh operation is performed on the memory cell corresponding to the selected word line. This operation is then repeated by changing bits from X0 to X12 and all memory cells in memory bank 50a are refreshed. A refresh operation is also likewise performed on other memory banks of memory array 5 shown in FIG. 1 and a refresh operation is performed on all memory cells of semiconductor device 100.

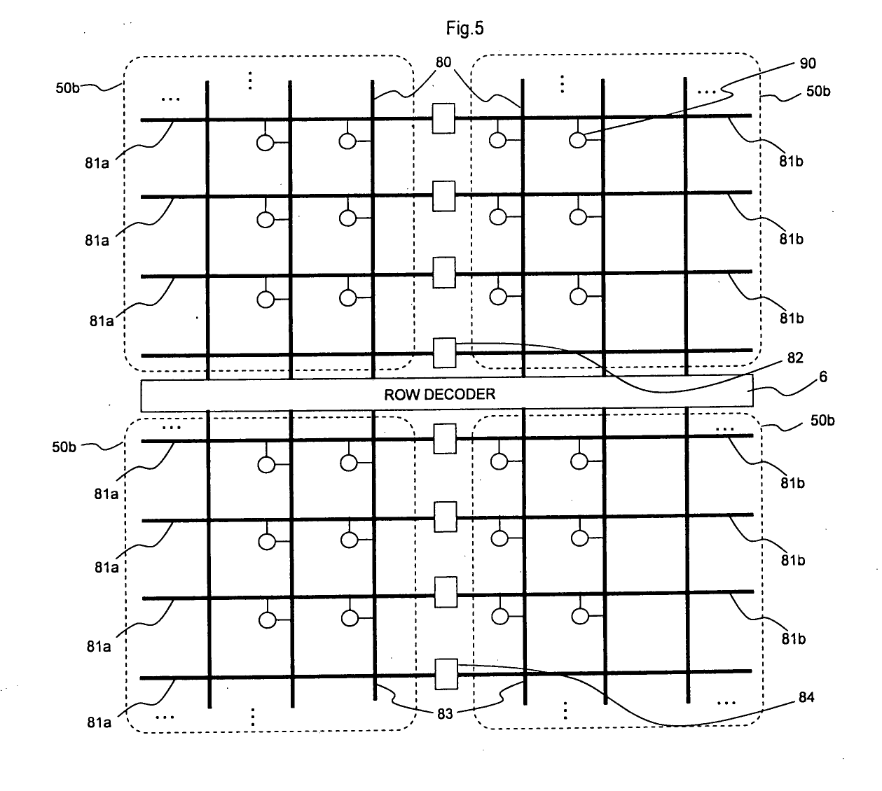

FIG. 5 illustrates a configuration example of part of memory bank 50a shown in FIG. 4. As shown in FIG. 5, X13=0 side word line 80 crosses a plurality of/bit lines 81a and bit lines 81b.

Furthermore, as shown in FIG. 5, X13=1 side word line 83 crosses a plurality of/bit lines 81a and bit lines 81b likewise.

Furthermore, as shown in FIG. 5, memory cells 90 are provided at points of intersection of/bit lines 81a or bit lines 81b and X13=0 side word lines 80. Likewise, memory cells 90 are provided between/bit lines 81a or bit lines 81b and X13=1 side word lines 83.

Furthermore, as shown in FIG. 5, sense amplifiers are provided between memory mats 50b. The sense amplifier amplifies data read from memory cell 90.

Hereinafter, the first sense amplifier corresponding to X13=0 side word line 80 will be referred to as “X13=0 side sense amplifier” and the second sense amplifier corresponding to X13=1 side word line 83 will be referred to as “X13=1 side sense amplifier.”

FIG. 5 illustrates a case where memory array 5 adopts an open bit scheme as an example, but the present invention is applicable irrespective of the configuration of the memory array.

The refresh operation by semiconductor device 100 in such a configuration will be explained below.

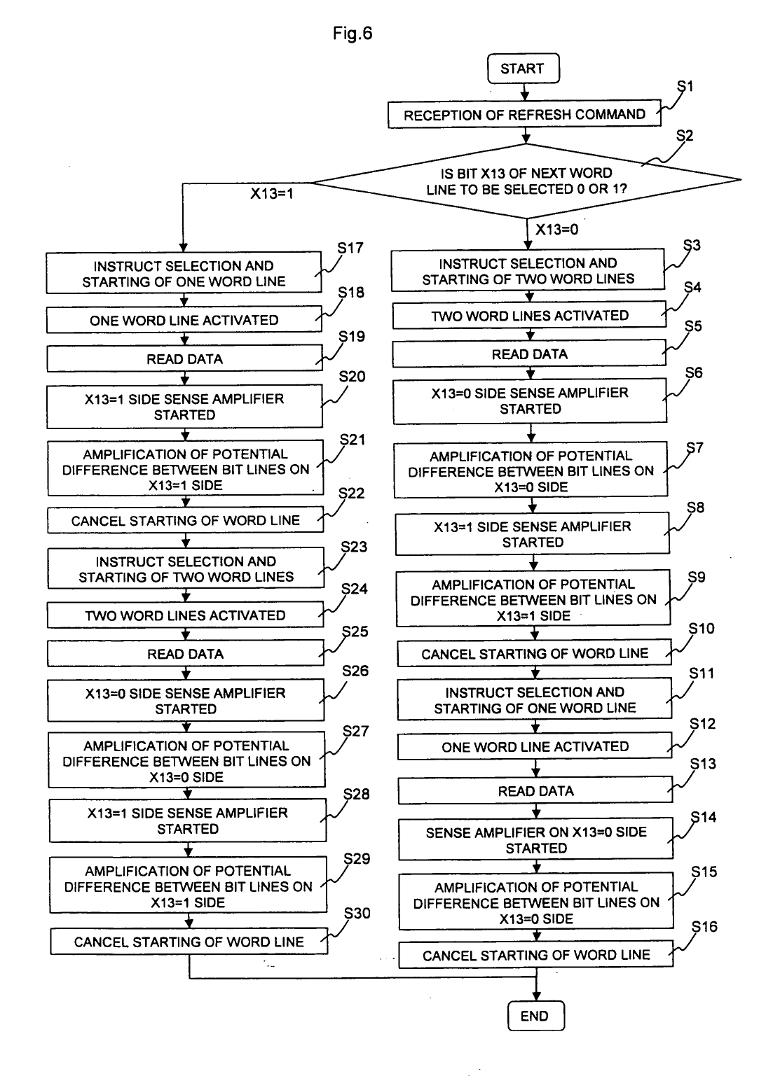

FIG. 6 is a flowchart for illustrating the refresh operation in semiconductor device 100 shown in FIG. 1 to FIG. 5.

First, controller 1 receives a refresh command from the outside of semiconductor device 100 such as a DRAM controller in step Si.

Next, controller 1 determines whether bit X13 of the next word line to be selected is 0 or 1 based on an address value already generated and counted up by refresh counter 2 in step S2.

When the determination result in step S2 shows that bit X13 of the next word line to be selected is 0, controller 1 outputs the first line number information indicating that two word lines are to be selected as the first word line selected to word line selector 3. Along therewith, controller 1 instructs X timing controller 4 to start the word lines in step S3. The instruction for X timing controller 4 to start the word line includes the line number information. This causes X timing controller 4 to determine the number of times the sense amplifier is started. The same will apply to a case where controller 1 instructs X timing controller 4 to start the word line in subsequent steps.

On the other hand, the case where the determination result in step S2 shows that bit X13 of the next word line to be selected is 1 will be described later.

Word line selector 3 that has received the output of the first line number information from controller 1 generates a row address of one X13=0 side word line 80 next to the counter address indicated by the address value already generated by refresh counter 2 and a row address of one X13=1 side word line 83, and outputs a total of two row addresses to row decoder 6. Furthermore, refresh counter 2 counts up counter addresses corresponding to these row addresses generated by word line selector 3 as the address values already generated on X13=0 side and X13=1 side respectively.

Thus, a total of two word lines; one X13=0 side word line 80 and one X13=1 side word line 83, are selected simultaneously.

X timing controller 4 that has received the instruction for starting the word lines in step S3 outputs an activation signal to control the timing of starting the word lines and thereby activates a total of two selected word lines; one X13=0 side word line 80 and one X13=1 side word line 83 in step S4.

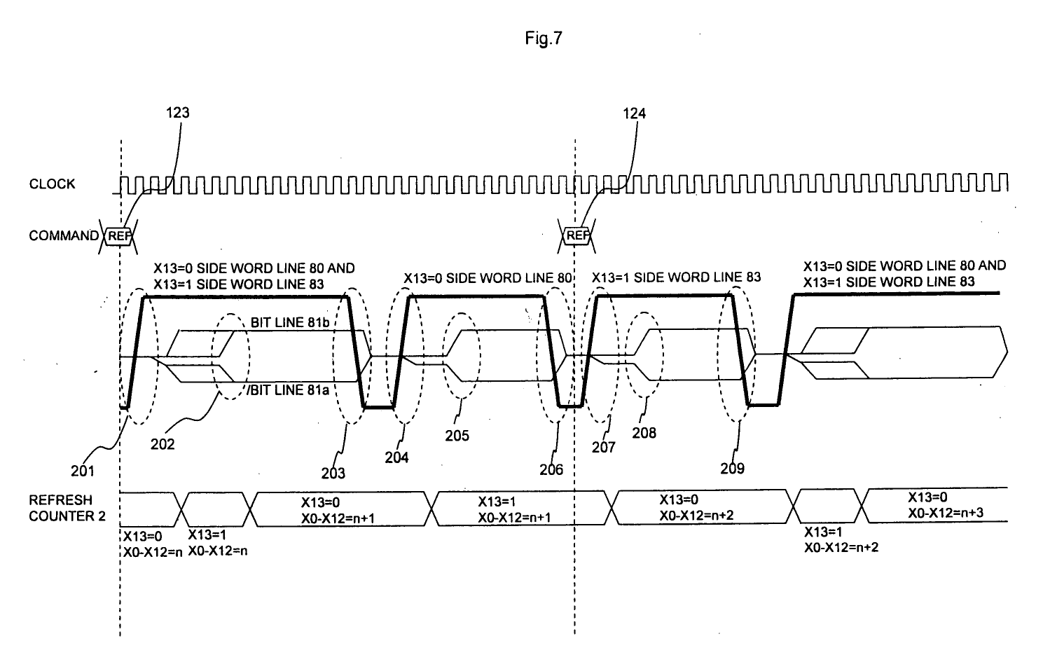

FIG. 7 is an operation waveform diagram showing voltage variations of the word lines and bit lines shown in FIG. 5.

As shown in word line activation 201 in FIG. 7, both one X13=0 side word line 80 and one X13=1 side word line 83 are selected, and both X13=0 side word line 80 and X13=1 side word line 83 are thereby activated.

When one X13=0 side word line 80 is activated, data is read from a plurality of memory cells 90 corresponding to activated one X13=0 side word line 80. That is, a potential difference corresponding to the data stored in memory cell 90 is generated between/bit lines 81 a and bit lines 81b. Furthermore, one X13=1 side word line 83 is activated simultaneously here. Therefore, data is also read from a plurality of memory cells 90 corresponding to activated one X13=1 side word line 83 in step S5.

Next, X timing controller 4 outputs activation signals to control the timings of starting X13=0 side sense amplifier 82 (see FIGS. 5) and X13=1 side sense amplifier 84. This causes all X13=0 side sense amplifiers 82 corresponding to activated X13=0 side word line 80 to start in step S6.

Started X13=0 side sense amplifier 82 causes a potential difference between/bit lines 81a and bit lines 81b to be amplified to a potential difference (e.g., grounding potential/power supply potential VDD) corresponding to a logical level of 0 or 1 as shown in bit lines amplification 202 in FIG. 7 and the charge is supplied to memory cell 90 in step S7.

In the amplification in step S7, in the case of an over-drive scheme, a charge is supplied from an over-drive compensation capacitance to memory cell 90 via an over-drive power supply line (not shown) while the over-drive starting signal is in a high level state. When the over-drive starting signal is driven low, the over-drive stops and the over-drive compensation capacitance is recharged. The same operation applies to the case where a potential difference between bit lines is amplified in the following steps.

After this, /bit lines 81a and bit lines 81b are precharged and the refresh of a plurality of memory cells 90 corresponding to activated one X13=0 side word line 80 is completed.

Next, all X13=1 side sense amplifiers 84 (see FIG. 5) corresponding to activated X13=1 side word line 83 start in step S8.

Started X13=1 side sense amplifiers 84 cause the potential difference between/bit lines 81a and bit lines 81b to be amplified to a potential difference corresponding to a logical level of 0 or 1 (e.g., grounding potential/power supply potential VDD) and a charge is supplied to memory cell 90 in step S9.

After this, /bit lines 81a and bit lines 81b are precharged and refresh of a plurality of memory cells 90 corresponding to activated one X13=1 side word line 83 is completed.

Here, X timing controller 4 cancels the starting of the word lines in step S10. As shown in word line inactivation 203 in FIG. 7, one X13=0 side word line 80 and one X13=1 side word line 83 are thereby inactivated. Furthermore, X timing controller 4 outputs end signal 115 (see FIG. 2 and FIG. 3) to controller 1.

Upon receiving end signal 115 outputted from X timing controller 4, controller 1 outputs second line number information indicating that one word line is selected as a selection of the second word line to word line selector 3. Along therewith, controller 1 instructs X timing controller 4 to start the word line in step S11.

Word line selector 3 that has received the output of the second line number information from controller 1 generates a row address of one X13=0 side word line 80 next to the counter address indicated by the address value generated by refresh counter 2 and outputs the row address to row decoder 6. Furthermore, refresh counter 2 counts up a counter address corresponding to the row address generated by this word line selector 3 as an address value generated on the X13=0 side. Here, X13=1 side word line 83 is not selected. The reason is to secure a time to supply charge to memory cell 90 located on the X13=0 side by securing the same time as the time during which X13=1 side sense amplifier 84 is started.

Thus, one X13=0 side word line 80 is selected.

X timing controller 4 that has received the instruction for starting the word line in step S11 outputs an activation signal to control the timing of starting the word line and selected one X13=0 side word line 80 is thereby activated in step S12. As shown in word line activation 204 in FIG. 7, one X13=0 side word line 80 is selected and one X13=0 side word line 80 is thereby activated.

When one X13=0 side word line 80 is activated, data is read from a plurality of memory cells 90 corresponding to activated one X13=0 side word line 80 in step S13.

Next, X timing controller 4 outputs an activation signal to control the timing of starting X13=0 side sense amplifier 82. This causes all X13=0 side sense amplifiers 82 corresponding to activated X13=0 side word line 80 to start in step S14.

Started X13=0 side sense amplifier 82 causes a potential difference between/bit lines 81 a and bit lines 81b as shown in bit lines amplification 205 in FIG. 7 to be amplified to a potential difference (e.g., grounding potential/power supply potential VDD) corresponding to a logical level of 0 or 1 and a charge is supplied to memory cell 90 in step S15.

Hereafter, /bit lines 81a and bit lines 81b are precharged and refresh of a plurality of memory cells 90 corresponding to activated one X13=0 side word line 80 is completed.

Here, X timing controller 4 cancels the starting of the word line in step S16. As shown in word line inactivation 206 in FIG. 7, X13=0 side word line 80 is inactivated. Furthermore, X timing controller 4 outputs end signal 115 to controller 1.

As described so far, a word line selection for a refresh is performed twice by one refresh command inputted from the outside of semiconductor device 100. This two-time word line selection corresponds to the number of times refresh clock signal 114 shown in FIG. 2 and FIG. 3 is outputted.

Here, when the determination result in step S2 shows that bit X13 of the next word line selected is 1, controller 1 outputs second line number information indicating that one word line is selected as the first word line selection to word line selector 3. Along therewith, controller 1 instructs X timing controller 4 to start the word line in step S17. The case where “bit X13 of the next word line to be selected is 1” assumes a case where the aforementioned operations from steps S1 to S16 are finished and controller 1 receives refresh command 124 shown in FIG. 7.

Word line selector 3 that has received the output of the second line number information from controller 1 generates a row address of one X13=1 side word line 83 next to the row address indicated by the address value generated by refresh counter 2 and outputs the row address to row decoder 6. Furthermore, refresh counter 2 counts up the counter address corresponding to the row address generated by this word line selector 3 as an address value generated on the X13=1 side.

Thus, one X13=1 side word line 83 is selected.

X timing controller 4 that has received an instruction for starting the word line in step S17 outputs an activation signal to control the timing of starting the word line and selected one X13=1 side word line 83 that is selected is thereby activated in step S18. As shown in word line activation 207 in FIG. 7, one X13=1 side word line 83 is selected and one X13=1 side word line 83 is thereby activated.

When one X13=1 side word line 83 is activated, data is read from a plurality of memory cells 90 corresponding to activated one X13=1 side word line 83 in step S19.

Next, X timing controller 4 outputs an activation signal to control the timing of starting X13=1 side sense amplifier 84. This causes all X13=1 side sense amplifiers 84 corresponding to activated X13=1 side word line 83 to start in step S20.

X13=1 side sense amplifier 84 that has started causes a potential difference between/bit lines 81a and bit lines 81b to be amplified to a potential difference corresponding to a logical level of 0 or 1 as shown in bit lines amplification 208 in FIG. 7 (e.g., grounding potential/power supply potential VDD) and a charge is supplied to memory cell 90 in step S21.

After this, /bit lines 81a and bit lines 81b are precharged and refresh of a plurality of memory cells 90 corresponding to activated one X13=1 side word line 83 is completed.

Here, X timing controller 4 cancels the starting of the word line in step S22. As shown in word line inactivation 209 in FIG. 7, this inactivates X13=1 side word line 83. Furthermore, X timing controller 4 outputs end signal 115 to controller 1.

Upon receiving end signal 115 outputted from X timing controller 4, controller 1 outputs first line number information that indicates to select two word lines as a second word line selection to word line selector 3. Along therewith, controller 1 instructs X timing controller 4 to start the word lines in step S23.

Word line selector 3 that has received the output of the first line number information from controller 1 generates a row address of one X13=0 side word line 80 next to the counter address indicated by the address value generated by refresh counter 2 and a row address of one X13=1 side word line 83 and outputs a total of two row addresses to row decoder 6. Furthermore, refresh counter 2 counts up counter addresses corresponding to these row addresses generated by word line selector 3 as the generated address values on the X13=0 side and X13=1 side.

This causes a total of two word lines; one X13=0 side word line 80 and one X13=1 side word line 83, to be selected simultaneously.

Operations in next steps S24 to S30 are the same as the aforementioned operations in steps S4 to S10, and therefore explanations thereof will be omitted.

These are the refresh operations in semiconductor device 100 shown in FIG. 1 to FIG. 5.

Thus, since a word line selection is performed twice by receiving one refresh command in the present embodiment, it is possible to increase the number of memory cells that can be refreshed by receiving one refresh command. This allows the time for refreshing all memory cells of the semiconductor device to be reduced. In the case of a 1 G-bit DRAM for example, all memory cells can be refreshed in 48 ms.

Furthermore, when a plurality of word lines are selected, sense amplifiers corresponding to the plurality of word lines are not started simultaneously, and it is thereby possible to reduce the burden on the power supply system of the memory array.

According to the present embodiment, a word line selection is performed twice by receiving one refresh command and a refresh operation is performed based on the first line number information and the second line number information, but the present embodiment can be changed based on the refresh period and the time necessary for the refresh operation.

For example, it is also possible to perform a word line selection three times by receiving one refresh command and to perform a refresh operation in order of first line number information, first line number information and second line number information. In this embodiment, a refresh operation is performed by a next refresh command in order of second line number information, first line number information and first line number information.

It is apparent that the present invention is not limited to the above embodiments, but may be modified and changed without departing from the scope and spirit of the invention.

What is claimed is:

1. A semiconductor device comprising a word line wired on a memory bank, a memory cell that stores data provided in correspondence with the word line and a sense amplifier provided in correspondence with the word line, refreshing the memory cell corresponding to the word line selected by a row address that is generated, comprising:
a refresh counter that generates a counter address corresponding to the row address and sequentially counts up the counter address;
a controller that determines and outputs, upon receiving a refresh command instructing that a refresh operation be performed, first line number information and second line number information determining a number of word lines to be started based on the counter address; and
a word line selector that determines and outputs the row address according to the first line number information and the second line number information, and the counter address.

2. The semiconductor device according to claim 1, wherein the memory bank is divided into a first region and a second region,
the word line is divided into a first word line corresponding to the first region and a second word line corresponding to the second region,
the first line number information comprises information from which the first word line and the second word line are selected, and
the second line number information comprises information from which either the first word line or the second word line is selected.

3. The semiconductor device according to claim 2, wherein the word line selector outputs, upon receiving the first line number information, row addresses corresponding to the first word line and the second word line of the counter addresses and outputs, upon receiving the second line number information, row addresses corresponding to the counter addresses.

4. The semiconductor device according to claim 3, further comprising an X timing controller that outputs a starting signal of the word line and a starting signal of the sense amplifier, wherein the sense amplifier is divided into a first sense amplifier corresponding to the first region and a second sense amplifier corresponding to the second region, and
the X timing controller outputs, upon receiving the first line number information from the controller, a first sense amplifier starting signal that starts the first sense amplifier and a second sense amplifier starting signal that starts the second sense amplifier on a time-division basis.

5. The semiconductor device according to any one of claims 2, wherein the refresh counter counts up, when the first line number information is outputted, the count address twice and counts up, when the second line number information is outputted, the count address once.

6. The semiconductor device according to any one of claims 2, wherein the controller consecutively outputs, upon receiving the refresh command, the first line number information and the second line number information within a refresh period.

7. The semiconductor device according to claim 6, wherein the controller outputs, when a lower address of the counter address indicates first lower information upon receiving the refresh command, the first line number information and then outputs the second line number information.

8. The semiconductor device according to claim 7, wherein the controller outputs, when the lower address of the counter address indicates second lower address information different from the first lower address information, the second line number information and then outputs the second line number information.

9. A semiconductor device comprising:
a memory bank divided into a first region and a second region;
a first word line provided in correspondence with the first region;
a second word line provided in correspondence with the second region;
a first memory cell provided in correspondence with the first word line storing data;
a second memory cell provided in correspondence with the second word line storing data;
a first sense amplifier provided in correspondence with the first word line;
a second sense amplifier provided in correspondence with the second word line;
a refresh counter that generates a counter address corresponding to a row address that selects the first word line and the second word line and sequentially counts up the counter address; and
a controller performs control, upon receiving a refresh command instructing that a refresh operation be performed, so as to perform refreshing a plurality of times within a refresh period.

10. The semiconductor device according to claim 9, wherein when the refresh command is inputted, the controller determines to simultaneously start the first word line and the second word line of the row address corresponding to the counter address based on the counter address or to start any one of the first word line and the second word line of the row address corresponding to the counter address.

11. The semiconductor device according to claim 10, wherein the controller performs control so as to simultaneously start the first word line and the second word line corresponding to the counter address and then starts the first word line corresponding to the counter address.

12. The semiconductor device according to claim 11, wherein the controller performs control so as to start the second word line corresponding to the counter address and then simultaneously start the first word line and the second word line corresponding to the counter address.

13. The semiconductor device according to any one of claims 10, wherein the refresh counter counts up, when the first word line and the second word line are started, the counter address twice, and counts up, when any one of the first word line and the second word line is started, the counter address once.

14. A refreshing method in a semiconductor device comprising a word line wired on a memory bank, a memory cell that stores data provided in correspondence with the word line and a sense amplifier provided in correspondence with the word line, refreshing the memory cell corresponding to the word line selected by a row address generated, comprising:
a process of selecting, upon receiving a refresh command instructing that a refresh operation be performed, first line number information and second line number information determining a number of word lines to be started based on a counter address indicated by a refresh counter; and
a process of determining the row address according to the first line number information and second line number information, and the counter address.

15. The refreshing method according to claim 14, wherein the memory bank is divided into a first region and a second region,
the word line is divided into a first word line corresponding to the first region and a second word line corresponding to the second region,
the first line number information comprises information from which the first word line and the second word line are selected, and
the second line number information comprises information from which either the first word line or the second word line is selected.

16. The refreshing method according to claim 15, further comprising a process of simultaneously starting the first word line and the second word line when the first line number information is selected and starting any one of the first word line and the second word line when the second line number information is selected.

17. The refreshing method according to claim 16, further comprising a process of starting, when the first line number information is selected, a first sense amplifier corresponding to the first word line and a second sense amplifier corresponding to the second word line on a time-division basis.

18. The refreshing method according to any one of claims 15, further comprising a process of counting up, when the first line number information is selected, the count address twice and counting up, when the second line number information is selected, the count address once.

19. The refreshing method according to any one of claims 15, further comprising:
a process of selecting, when the refresh command is received, the first line number information and starting the first word line and the second word line; and
a process of selecting the second line number information and starting either the first word line or the second word line consecutively within a refresh period.

20. The refreshing method according to claim 19, wherein the word line is started twice within a refresh period.
